(19) United States
(12) Patent Application Publication
(10) Pub. No.: US 2009/0243035 A1
(43) Pub. Date: Oct. 1, 2009

(54) SEMICONDUCTOR DEVICE AND METHOD OF MANUFACTURING THE SAME AND SEMICONDUCTOR DEVICE MOUNTING STRUCTURE

(75) Inventor: Naohiro MASHINO, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/408,927

(22) Filed: Mar. 23, 2009

(30) Foreign Application Priority Data
Mar. 28, 2008 (JP) P.2008-88100

(51) Int. Cl. H01L 23/488; H01L 21/98

(52) U.S. Cl. 257/531; 438/107; 257/E21.705; 257/E23.023

(57) ABSTRACT

In a semiconductor device that is formed by joining two semiconductor elements together to oppose device layers to each other, inductor patterns for transmitting and receiving a signal and feeding a power and bumps for connecting electrically the semiconductor elements and for supporting the inductor patterns and the semiconductor elements being arranged opposedly in an electrically isolated state are provided on a surface of the device layer of at least one of semiconductor elements and an electrically insulating material is filled in a space between opposing surfaces of the semiconductor elements.

### TECHNICAL FIELD

The present disclosure relates to a semiconductor device and a method of manufacturing the same and a semiconductor device mounting structure. More particularly, the present disclosure relates to a semiconductor device having a structure in which a plurality of semiconductor elements are stacked and a method of manufacturing the same and a semiconductor device mounting structure.

### RELATED ART

Out of the semiconductor devices in which semiconductor elements are mounted, the product in which a plurality of semiconductor elements are stacked has been provided to achieve a reduction in size and thickness of the semiconductor device.

As the method of mounting the semiconductor elements in a stacked fashion, following methods can be considered. That is, (1) a mounting method of connecting the lower semiconductor element to the wiring substrate by the flip-chip bonding and then connecting an upper semiconductor element to the lower semiconductor element by the wire bonding, (2) a mounting method of stacking semiconductor elements while using an interposer and then connecting electrically the semiconductor elements and the interposer, and (3) a mounting method of providing electric connection portions such as through electrodes, for example, to semiconductor elements and then stacking the semiconductor elements such that the semiconductor elements are connected electrically via the electric connection portions mutually.

[Patent Literature 1] JP-A-2002-305282

[Patent Literature 2] JP-A-2001-351827

[Patent Literature 3] JP-A-2003-337310

By the way, in order to achieve a size reduction and a thickness reduction of a resultant structure as much as possible in a situation that several semiconductor elements are stacked, the mounting method of stacking the semiconductor elements only not to interpose the interposer is effective. However, in the case of the mounting method of stacking only the semiconductor elements, it is feared that, since the electric connection portions such as the through electrodes, or the like are provided to the semiconductor elements, the semiconductor element are damaged. Also, such a problem exists that, since several semiconductor elements are stacked while providing the electric connection between them, reliability of the electric connection and manufacturing yield as the whole semiconductor device are lowered.

### SUMMARY

Exemplary embodiments of the present invention provide a semiconductor device and a method of manufacturing the same and a semiconductor device mounting structure, capable of providing an electric connection between semiconductor elements without fail, facilitating works to stack the semiconductor elements, and achieving a size reduction of a resultant structure effectively when a plurality of semiconductor elements are to be stacked.

According to an exemplary embodiment of the present invention, there is provided a semiconductor device comprising: two semiconductor elements, each having a device layer, the two semiconductor elements being jointed together to oppose the respective device layers to each other, at least one of semiconductor elements having an inductor pattern and a bump on a surface of the device layer, the bump connecting electrically the semiconductor elements and supporting and electrically isolating the inductor pattern and the opposedly arranged semiconductor element; and an electrically insulating material filled in a space between opposing surfaces of the semiconductor elements. The inductor pattern may used for transmitting and receiving a signal or for feeding a power.

In this case, the wording “electrically isolating the inductor pattern and the opposedly arranged semiconductor element” means that an electric short-circuit between the opposedly arranged semiconductor element and the inductor pattern in a state that the semiconductor elements are arranged to oppose to each other should be prevented. As one method, the inductor pattern and the opposedly arranged semiconductor element should be arranged at a distance not to cause an electric short-circuit between the inductor pattern and the opposedly arranged semiconductor element.

There is no necessity that both inductor patterns used to transmit and receive the signal and feed the power should always be provided as the inductor patterns formed on the semiconductor elements. Such a configuration may be employed that the inductor pattern used to transmit and receive the signal or feed the power is provided. Also, the inductor pattern may be provided to one of semiconductor elements constituting the semiconductor device only. Also, all of shapes and sizes of the semiconductor elements constituting the semiconductor device do not coincides with each other.

Also, at least one inductor pattern for transmitting and receiving the signal and at least one inductor pattern for feeding the power are provided to the semiconductor elements respectively. Since the inductor patterns used to transmit and receive the signal and feed the power are provided to both semiconductor elements, the signal transmission and reception and the power feeding can be carried out between the semiconductor elements in mounting the stacked body being formed by stacking the semiconductor devices on the wiring substrate, or the like. Therefore, the preferred semiconductor mounting structure can be accomplished.

Also, the inductor pattern is provided to surfaces of the device layers of both semiconductor elements respectively to oppose to each other. Therefore, the handling such as the assembling of the stacked body by stacking the semiconductor devices, and the like can be facilitated.

Also, a method of manufacturing a semiconductor device, includes a step of forming an inductor pattern on a surface of a device layer formed on a semiconductor wafer; a step of forming a bump on the surface of the device layer formed on the semiconductor wafer; a step of arranging two semiconductor wafers, on each of which the inductor pattern and the bump are formed, to oppose respective device layers to each other, and joining the bumps together; a step of filling an electrically insulating material into a space between opposing surfaces of two semiconductor wafers being joined via the bumps to form a jointed body; and a step of forming individual semiconductor devices, by dicing the joined body into individual pieces. The inductor pattern may be used for transmitting and receiving a signal or for feeding a power.

Also, in the step of forming the bump, a solder bump is formed as the bump and, in the step of joining the bumps, the bumps are joined by a reflow soldering.

Also, a method of manufacturing a semiconductor device, includes a step of forming an inductor pattern on a surface of a device layer formed on a semiconductor wafer; a step of forming a gold bump on the surface of the device layer formed on the semiconductor wafer; a step of interposing an anisotropic conductive resin between opposing surfaces of two semiconductor wafers on each of which the inductor pattern and the gold bump are formed, and connecting electrically the opposing gold bumps and filling the anisotropic conductive resin into a space between the opposing surfaces of the two semiconductor wafers by pressing the two semiconductor wafers from both surface sides to form a jointed body; and a step of forming individual semiconductor devices, by dicing the joined body into individual pieces. The inductor pattern may be used for transmitting and receiving a signal or for feeding a power.

According to this manufacturing method, since the gold bumps are employed as the bumps, a clearance between the semiconductor elements arranged opposedly can be set narrower than that in the case where the solder bumps are employed. Also, since the method of joining the semiconductor elements via the anisotropic conductive resin is employed, a clearance between the semiconductor elements arranged opposedly can be narrowed rather than the method of filing the resin between the semiconductor elements after the semiconductor elements are joined, and thus a size reduction of the semiconductor device can be achieved.

Also, a semiconductor device mounting structure, comprises: a wiring substrate; and the above-mentioned semiconductor device mounted on the wiring substrate, wherein the wiring substrate has another inductor pattern formed in an position opposed in planarly to the inductor pattern provided to the semiconductor device so that an electromagnetic inducing action is produced between the another inductor pattern and the inductor pattern provided to the semiconductor device. The inductor pattern and the another inductor pattern may be used for transmitting and receiving a signal or for feeding a power.

Also, a plurality of the semiconductor device are stacked to form a stacked body, and the semiconductor devices constituting the stacked body are provided in positions, in which the inductor patterns provided on neighboring semiconductor elements oppose planarly to each other, between the semiconductor devices located in neighboring positions in a stacking direction. Accordingly, the signal transmission and reception and the power feeding between the semiconductor devices stacked and mounted is enabled.

Also, the inductor patterns provided to the semiconductor devices constituting the stacked body are provided in common positions having same planar positions in all semiconductor devices. Therefore, the stacked body of the semiconductor devices can be formed easily by standardizing the semiconductor devices.

According to the semiconductor device according to the present invention, the signal transmission and reception between the semiconductor elements and the power feeding are conducted via the inductor patterns, and therefore the electric connection between the semiconductor elements can be provided surely, and the semiconductor elements can stacked and formed in a compact mode. Also, the semiconductor device stacked body can be formed not to damage the device layer, and can be provided as the semiconductor device that is ready to manufacture and assemble. Also, according to the semiconductor device mounting structure according to the present invention, the signal transmission and reception between the wiring substrate and the semiconductor elements and the power feeding can be easily provided. Also, according to the method of manufacturing the semiconductor device according to the present invention, the semiconductor device equipped with the inductor patterns can be easily manufactured.

Other features and advantages may be apparent from the following detailed description, the accompanying drawings and the claims.

### BRIEF DESCRIPTION OF THE DRAWINGS

FIGS. 1A to 1E are sectional views showing steps of manufacturing a semiconductor device.

FIG. 2 is a sectional view showing an inductor pattern having a magnetic layer.

FIGS. 3A to 3D are sectional views showing steps of manufacturing a semiconductor device.

FIGS. 4A and 4B are sectional views showing another manufacturing method of a semiconductor device.

FIGS. 5A and 5B are sectional views showing another configurative example of a semiconductor device.

FIG. 6 is a sectional view showing a semiconductor device mounting structure.

FIG. 7 is a sectional view showing the semiconductor device mounting structure in an enlarged fashion.

### DETAILED DESCRIPTION

A semiconductor device and a method of manufacturing the same and a semiconductor device mounting structure according to the present invention will be explained with reference to the accompanying drawings hereinafter.

(Method of Manufacturing Semiconductor Device)

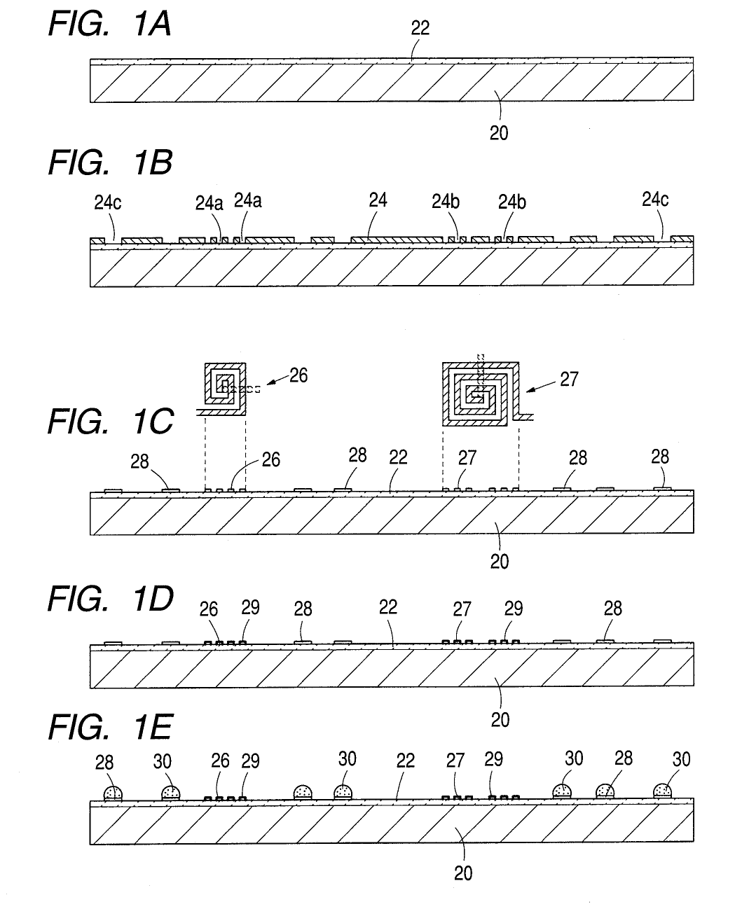

FIGS. 1A to 5B show a method of manufacturing a semiconductor device according to the present invention.

In the method of manufacturing the semiconductor device according to the present invention, predetermined processes are applied to a semiconductor wafer, and then the semiconductor wafer is diced into individual pieces as the semiconductor devices.

FIG. 1A is a sectional view showing of a wafer (semiconductor wafer) 20 on a surface of which devices are formed. A device layer 22 in which the devices are formed is provided on a surface (active surface) of the wafer 20.

FIG. 1B shows a state that a resist pattern 24 used to form wiring patterns for the electric connection and inductor patterns are formed on a surface of the device layer 22 of the wafer 20. The wiring patterns and the inductor patterns can be formed by applying a method of manufacturing the wiring pattern in steps of manufacturing a wafer level package, or the like.

In this case, the inductor patterns are provided for the purpose of transmitting and receiving signals between the semiconductor devices and feeding a power (power feeding). The inductor patterns are formed to have a coil-like planar shape.

In the accompanying drawings explained hereinafter, for convenience of explanation, the illustration of the wafer 20 shows one unit area of the semiconductor device that is formed from the wafer 20. Respective unit areas are aligned and arranged longitudinally and laterally on the wafer 20, and the wiring pattern and the inductor pattern are shaped into the same pattern in every unit area respectively.

When the wiring pattern and the inductor pattern are formed by the semi-additive process, for example, first a plated seed layer is formed on a surface of the device layer 22 of the wafer 20, then this plated seed layer is coated with a dry film resist, and then the resist pattern 24 is formed by exposing and developing the dry film resist. A concave groove is formed in the resist pattern 24 to match with planar shapes of the wiring pattern and the inductor pattern. The plated seed layer is exposed from an inner bottom surface of the concave groove.

Then, the electroplating (e.g., the Cu electroplating) is applied while using the plated seed layer as a plating power feeding layer. Thus, a copper plated film (conductor portion) is formed in the concave groove to rise.

Then, the resist pattern 24 is removed, and then the plated seed layer for covering the surface of the device layer 22 is removed from areas of the plated seed layer except the area in which the wiring pattern and the inductor pattern are formed. Thus, the wiring pattern and the inductor pattern are formed on the surface of the device layer 22 as independent patterns. Since the plated seed layer is formed very thin, the exposed portions of the plated seed layer (portions except the area in which the wiring pattern and the inductor pattern are formed) can be selectively removed when the chemical etching is applied to the overall surface of the wafer 20.

The surface of the device layer 22 is covered with a passivation film, and electrodes are exposed from the passivation film. The wiring pattern and the inductor pattern are connected electrically to the electrodes.

FIG. 1B shows a state the resist pattern 24 is formed. In FIG. 1B, such a state is shown that a concave groove 24a used to form the inductor pattern for the signal transmission and reception, a concave groove 24b used to form the inductor pattern for the power feeding, and a concave groove 24c used to form the wiring pattern are formed.

FIG. 1C shows a state that an inductor pattern 26 for the signal transmission and reception, an inductor pattern 27 for the power feeding, and the wiring pattern are formed on the surface of the device layer 22. As the wiring pattern, portions of pads 28 to which bumps are joined are shown.

In FIG. 1C, planar shapes of the inductor patterns 26, 27 shaped like a coil respectively are also shown. The inductor patterns 26, 27 can be formed by setting adequately a line width, a pattern interval, and the number of patterns. By way of example, when a line width of the inductor pattern is set to 10 μm, a pattern interval is set to 10 μm, and a size of the inductor pattern is set to 0.7 mm×0.7 mm (square shape), the number of turns of the inductor pattern becomes 5 turns and also an inductance becomes about 23 nH. Also, when a line width of the inductor pattern is set to 20 μm, a pattern interval is set to 10 μm, and a size of the inductor pattern is set to 1.3 mm×1.3 mm, the number of turns of the inductor pattern becomes 13 turns and also an inductance becomes about 200 nH.

A size of the semiconductor device varies depending on the product. Therefore, a size of the inductor patterns 26, 27, the number of patterns, positions of patterns, and the number of turns may be set to meet a size of the product and standards on the product.

The above semi-additive process is effective as the method of forming the wiring pattern and the inductor pattern as fine patterns. But the method of forming the wiring pattern and the inductor pattern is not limited to this semi-additive process.

FIG. 1D shows a state that surfaces of the inductor patterns 26, 27 are covered with a magnetic layer 29 in next step.

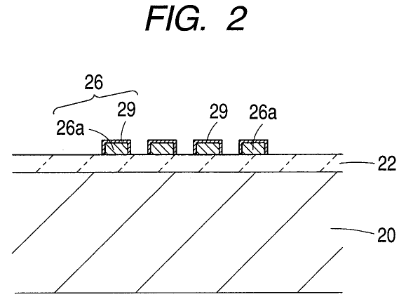

FIG. 2 show a state that the surface of the inductor pattern 26 is covered with the magnetic layer 29, in an enlarged fashion. In FIG. 2, such a state is shown that a surface of a conductor portion 26a of the inductor pattern 26 is covered with the magnetic layer 29.

As the method of covering the surfaces of the inductor patterns 26, 27 with the magnetic layer 29, the electroless plating method, the sputtering method, and the like can be utilized.

In the case of the method of forming the magnetic layer 29 by the electroless plating method, such an advantage is provided that a plated film can be deposited and formed selectively on portions (conductor portions) in which the inductor patterns 26, 27 are formed. As the magnetic layer 29, NiCo, NiFe, NiFeCo, ferrite, or the like is employed.

When the magnetic layer 29 is formed by the sputtering method, a surface of the wafer 20 is covered with a resist to expose the inductor patterns 26, 27, and then the sputtering is applied.

In addition to the electroless plating method and the sputtering method, the method of coating a resin material containing the magnetic material on outer surfaces of the inductor patterns 26, 27 by the printing method may be employed.

Because the magnetic layer 29 is deposited and formed on the outer surfaces of the inductor patterns 26, 27, an inductance of the inductor patterns 26, 27 can be increased. Thus, a coupling effect (electromagnetic inducing action) between the inductor patterns 26, 27 of the semiconductor elements can be enhanced. An action caused by the inductor patterns 26, 27 will be described later.

FIG. 1E shows a state that a bump 30 is joined to the pads 28 formed on the wiring pattern respectively after the magnetic layer 29 is formed on the surfaces of the inductor patterns 26, 27.

In forming the bumps 30, the method of supplying the solder to the pads 28 by the printing method and then forming solder bumps by the reflow soldering, the method of using the solder balls the copper core, the method of forming the bumps by ball bonding using a gold wire, and the like can be applied.

For the purpose of supporting a pair of semiconductor elements arranged opposedly at a predetermined interval and also coupling the semiconductor elements in a state that they are connected electrically mutually, the bumps 30 are provided. Therefore, any conductor material may be employed appropriately as the bump 30 to have an appropriate size if such material can perform the above actions.

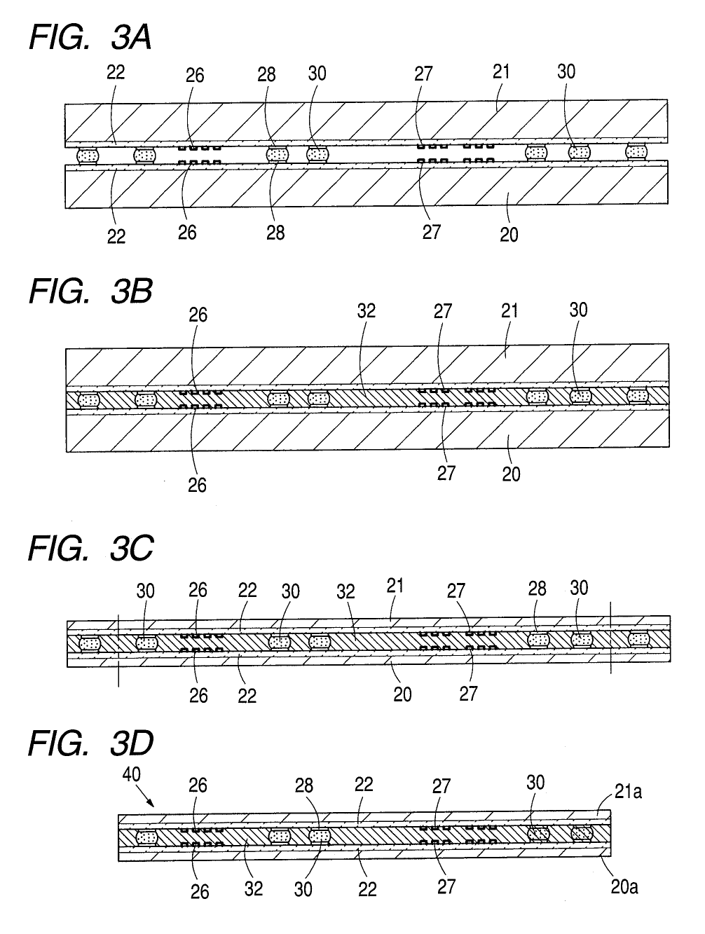

FIG. 3A shows subsequent steps to form the semiconductor device, and shows a state that two sheets of wafers 20, 21 are pasted via the bumps 30 such that their device layers 22, 22 (active surfaces) are opposed to each other. Two sheets of wafers 20, 21 are joined mutually by the bumps 30. Therefore, the bumps 30 formed on the wafers 20, 21 must be provided in advance such that their planar positions coincide with each other when the wafers 20, 21 are arranged to oppose to each other.

When the solder bumps are provided by the bumps 30, the wafers 20, 21 are aligned by a holding jig and supported, and then the reflow soldering is applied. Thus, the wafers 20, 21 can be joined together via the bumps 30. FIG. 3A shows a state that the wafers 20, 21 are joined by the solder bumps. The inductor patterns 26, 27 formed on the surfaces of the device layers 22, 22 of the wafers 20, 21 are set in a distant state.

It is not needed that the inductor patterns 26, 27 formed on the wafers 20, 21 respectively should be provided such that their planar positions coincide with each other when the wafers 20, 21 are arranged to oppose to each other. This is because, as described later, the action for transmitting and receiving the signal and feeding the power by utilizing the electromagnetic inducing action between the inductor patterns 26, 27 should not be provided between the semiconductor elements that are joined via the bumps 30. In the present embodiment, the inductor patterns 26, 27 formed on one wafer 20 and the inductor patterns 26, 27 formed on the other wafer 21 are arranged to oppose to each other. The reason why the inductor patterns 26, 27 are arranged opposedly is that, when the semiconductor device is assembled or packaged by stacking several semiconductor elements, the same arrangement of the inductor patterns 26, 27 of respective semiconductor elements facilitates the handling. Also, when arrangement of the bumps 30 on the wafer and arrangement of the inductor patterns 26, 27 are standardized and unified, such an advantage can be provided that mass production of the wafer can be made easy.

Two sheets of wafers 20, 21 are pasted together, and then a protection resin 32 is filled into a space between the opposing surfaces of the wafers 20, 21 such that this space between the opposing surfaces of the wafers 20, 21 is sealed with the resin 32 (FIG. 3B). As the resin 32, it would be better to employ the resin material such as an underfill resin, or the like, which is used for the flip-chip bonding of the semiconductor chip and whose flowability is good. In this way, the wafers 20, 21 are joined together by filling the resin 32 into a space between the opposing surfaces of the wafers 20, 21 and then thermally curing this resin. Since the wafers 20, 21 are integrated by the resin 32 filled into the space between the opposing surfaces of the wafers 20, 21, the interaction between the semiconductor elements in the packing operation can be relieved and also joinability and reliability of the semiconductor elements can be improved.

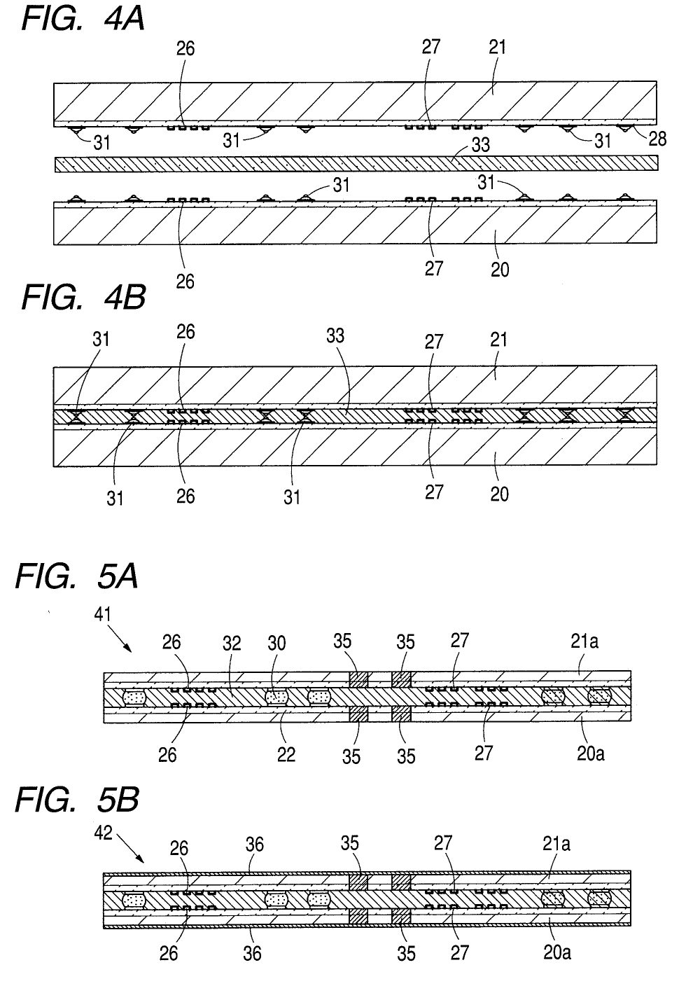

FIG. 4 shows another method of opposing two sheets of wafers 20, 21 and pasting together them. In the present embodiment, gold bumps 31 are joined to the pads 28, and then two sheets of wafers 20, 21 are joined together via the gold bumps 31.

As the method of joining the wafers 20, 21 via the gold bumps 31, the method of putting an anisotropic conductive film 33 between the opposing surfaces of the wafers 20, 21 and applying a heat and a pressure to the wafers 20, 21 via the anisotropic conductive film 33 is effective. When the wafers 20, 21 are pressed from both surface sides, the gold bumps 31 being arranged opposedly are connected electrically via the anisotropic conductive film 33 respectively. Also, the space between the opposing surfaces of the wafers 20, 21 is filled and sealed with the resin (having an insulating property) formed of the anisotropic conductive film 33, and thus the wafers 20, 21 are integrated together.

The method of employing the gold bumps 31 and the anisotropic conductive film 33 can made a clearance between the wafers 20, 21 narrower than that given by the method of pasting the wafers 20, 21 together by using the solder bumps. As a result, a size reduction of the semiconductor device can be achieved.

After two sheets of wafers 20, 21 are pasted together, the wafers 20, 21 are thinned by grinding the back surfaces (surfaces on the opposite side to the device layer 22) of the wafers 20, 21 (thinning process). FIG. 3C shows the thinning process is applied to the wafers 20, 21.

In order to attain a size reduction and a thickness reduction of the semiconductor device, the process of thinning the thickness by grinding the back surface of the wafer has been conventionally applied. In the manufacturing steps of the present embodiment, the thinning process is applied to the wafers 20, 21 in a state that two sheets of wafers 20, 21 are pasted together to direct their device layers 22, 22 to the inner side. Therefore, the wafers 20, 21 can be processed while still keeping their shapes, and also finished thicknesses of the wafers can be made thinner respectively than the case where a single sheet of wafer is processed. Also, the joined surfaces of the wafers 20, 21 are protected by the resin 32. Therefore, such an advantage can be provided that it can be prevented that the device layers 22, 22 of the wafers 20, 21 are damaged during the grinding process.

(Semiconductor Device)

After the back surfaces of the wafers 20, 21 are ground, a semiconductor device 40 is formed by dicing the wafer joined body (pasted body) into individual pieces. FIG. 3D shows the semiconductor device 40 that is obtained by dividing the wafer pasted body into individual pieces.

Semiconductor elements 20a, 21a formed by dividing the wafers 20, 21 into individual pieces respectively are formed integrally such that the device layers 22, 22 on the surfaces of which the inductor patterns 26, 27 are formed respectively are opposed to each other and also the resin 32 is filled into the space between the opposing surfaces of the semiconductor elements 20a, 21a.

In this semiconductor device 40, the semiconductor elements 20a, 21a are joined together via the bumps 30 formed of the solder bumps. In the above example shown in FIG. 4B, the semiconductor elements 20a, 21a are joined together via the gold bumps 31.

FIGS. 5A and 5B show another configurative example of the semiconductor device.

A semiconductor device 41 shown in FIG. 5A illustrates an example in which through electrodes 35 are provided to the semiconductor elements 20a, 21a. The through electrodes 35 are provided to provide the electric connection between the semiconductor devices 41 when the semiconductor devices 41 are packaged in a stacked fashion.

The through electrodes 35 can be formed by forming connection holes in the wafers 20, 21 by the plasma etching, or the like in a state that the wafers 20, 21 are pasted together (a state shown in FIG. 3B), and then filing a conductor into the connection holes by the plating, or the like.

Since the process of forming the connection holes is applied from the back surface side of the wafers 20, 21 in a state that the wafers 20, 21 are pasted together, such an advantage can be provided that the through electrodes 35 can be formed not to damage the device layers 22, 22 of the wafers 20, 21. The through electrodes 35 can be formed in any position respectively. However, since the semiconductor devices that are located in stacked positions are connected electrically mutually, it would be better to enhance commonality of positions where the through electrodes 35 are arranged.

A semiconductor device 42 shown in FIG. 5B illustrates an example in which an adhesion auxiliary layer 36 is provided on the back surfaces of the semiconductor elements 20a, 21a respectively. The adhesion auxiliary layer 36 is provided to improve an adhesive property of the semiconductor device 42 in mounting the semiconductor device 42 in a stacked fashion. When the back surfaces of the semiconductor elements 20a, 21a are still kept as the polished surfaces of the silicon wafers respectively, in some cases it is impossible to get a sufficient adhesion strength in adhering and joining the semiconductor devices. In view of the above fact, the adhesion auxiliary layer 36 is provided.

As the method of forming the adhesion auxiliary layer 36 on the back surfaces of the semiconductor elements 20a, 21a, there are the method of coating a resin material such as polyimide resin, or the like that has a good adhesive property to the adhesive agent, the method of coating a liquid, e.g., silane coupling material, to improve an adhesion strength, the method of applying the plasma process to the back surfaces of the semiconductor elements 20a, 21a, the method of applying the plating such as the nickel plating, or the like that has a good adhesive property to the adhesive agent, and the like. The method of applying the plasma process to the semiconductor elements 20a, 21a is applied to roughen the back surfaces of the semiconductor elements 20a, 21a and improve an adhesive property of the resin by the anchor action.

(Semiconductor Device Mounting Structure)

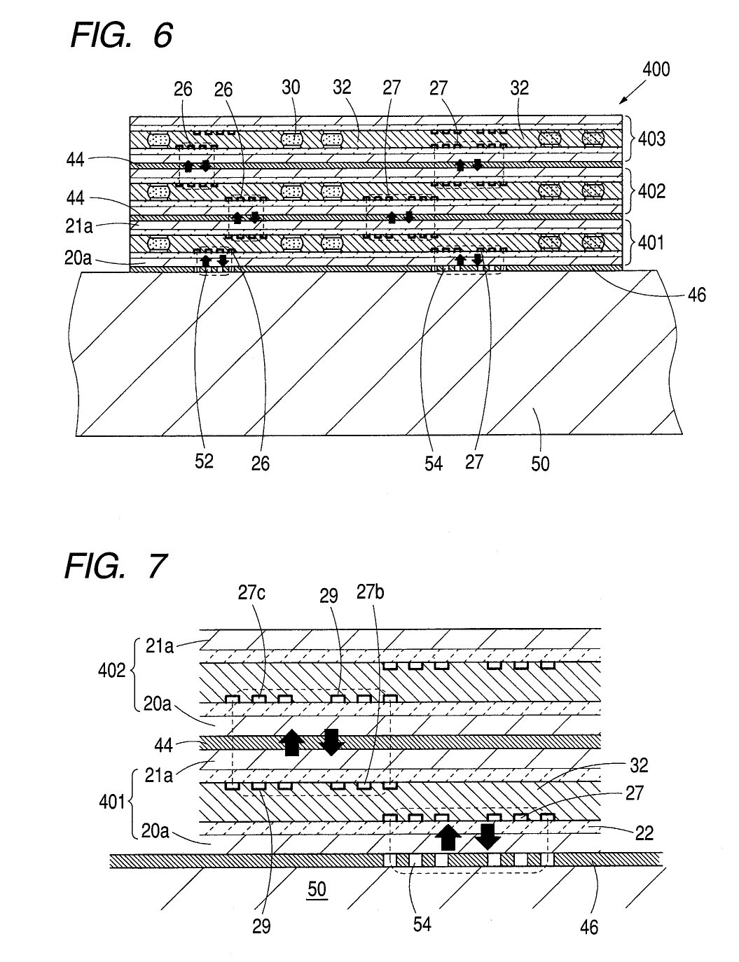

FIG. 6 shows a state that semiconductor devices 401, 402, 403 formed by the above method are mounted on the wiring substrate 50.

In order to mount the semiconductor device according to the present invention on a wiring substrate 50, first a stacked body of the semiconductor devices is formed, and then this stacked body is joined to the wiring substrate. The stacked body of the semiconductor devices can be formed by pacing an adhesive film between the semiconductor devices to be stacked respectively, and then integrating them by applying a pressure and a heat.

In FIG. 6, a stacked body 400 that is formed by stacking the semiconductor devices 401, 402, 403 via an adhesive layer 44 respectively is shown.

The stacked body 400 is aligned with the wiring substrate 50, and is joined to the wiring substrate 50 via an adhesive layer 46.

The semiconductor device 40 is constructed such that the device layers 22, 22 are put between the semiconductor elements 20a, 21a as inner layers and the device layers 22, 22 are not exposed on the surface. Therefore, there are such advantages that there is no danger that the device layers 22, 22 are damaged in forming the stacked body 400 by stacking the semiconductor devices 40 via the adhesive layer 44 respectively, and the stacked body 400 can be easily assembled. An example where three semiconductor devices 40 are stacked is illustrated. But the number of stacked layers of the semiconductor devices 40 is not limited to this, and the larger number of layers may be stacked.

Here, in order to explain plainly the actions of transmitting and receiving the signal between the semiconductor elements and feeding a power by using the inductor patterns 26, 27, an example in which the inductor patterns 26, 27 formed in the semiconductor element 20a and the inductor patterns 26, 27 formed in the semiconductor element 21a are displaced mutually, unlike the semiconductor device 40 shown in FIG. 3D, is shown in FIG. 6.

The signal transmission and reception and the power feeding between the wiring substrate 50 and the stacked body of the semiconductor devices are performed as follows.

The signal transmission and reception between the stacked body 400 of the semiconductor devices and the wiring substrate 50 is carried out between the inductor pattern 26 formed on the semiconductor element 20a in the lowermost layer of the stacked body 400 (the semiconductor element 20a arranged just above the wiring substrate 50) and an inductor pattern 52 that is formed on the surface of the wiring substrate 50 to have the same planar arrangement (opposing arrangement) as the inductor pattern 26. Similarly, the power supply (power feeding) between the stacked body 400 and the wiring substrate 50 is carried out between the inductor pattern 27 formed on the semiconductor element 20a in the lowermost layer of the stacked body 400 and an inductor pattern 54 formed on the surface of the wiring substrate 50 to oppose to the inductor pattern 27.

The signal transmission and reception between the inductor pattern 52 and the inductor pattern 26 is executed based on the action that an induced current is produced when an alternating current is applied to the inductor pattern 52 at a predetermined frequency. The power supply between the inductor pattern 54 and the inductor pattern 27 is executed based on the action that an induced electromotive force is produced when an alternating current is applied to the inductor pattern 54 at a predetermined frequency.

FIG. 7 shows respective arrangements of the inductor pattern 54 provided to the wiring substrate 50 and the inductor pattern 27 formed on the device layer 22 of the semiconductor element 20a in an enlarged fashion. FIG. 7 shows that the inductor pattern 54 and the inductor pattern 27 are arranged to face to each other and the electric power is supplied between these inductor patterns 27, 54 by the action of electromagnetic induction.

The semiconductor element 20a and the semiconductor element 21a are connected electrically to each other via the bumps 30. Therefore, the power supply between the semiconductor element 20a and the semiconductor element 21a is conducted via the wiring patterns electrically connected to the bumps 30.

The power supply between the semiconductor element 21a and the semiconductor element 20a in the semiconductor device 402 of the next layer is conducted based on the electromagnetic inducing action between an inductor pattern 27b formed in the semiconductor element 21a and an inductor pattern 27c formed in the semiconductor element 20a of the next layer. In other words, an induced electromotive force is generated in the inductor pattern 27c by applying an alternating current to the inductor pattern 27b at a predetermined frequency, so that the electric power is fed to the semiconductor element 20a of the next layer.

In the semiconductor device 402 of the next layer, the power supply from the semiconductor element 20a to the semiconductor element 21 a is performed via bumps 30a. Also, the power supply between the semiconductor device 402 and the semiconductor device 403 in the upper layer is performed similarly.

Also, the signal transmission and reception between the wiring substrate 50 and the semiconductor devices 401, 402, 403 constituting the stacked body 400 is conducted based on the totally same action as the power supply explained above. In other words, the signal transmission and reception between the wiring substrate 50 and the semiconductor element 20a of the semiconductor device 401 is executed by the induced current produced between the inductor patterns 26, 52, and also the signal transfer between the semiconductor element 20a and the semiconductor element 21a is executed via the electric connections given by the bumps 30 and the wiring patterns. Also, the signal transfer between the semiconductor element 21a and the semiconductor element 20a of the semiconductor device 402 in the next layer is executed via the inductor patterns 26, 26 formed on the semiconductor elements respectively.

In the semiconductor device of the present embodiment, the magnetic layer 29 is deposited and formed on the surface of the conductor portion of the inductor pattern 27 in the manufacturing steps. As shown in FIG. 7, the semiconductor devices are stacked sequentially and are mounted on the wiring substrate 50. Therefore, when portions of the inductor patterns 27b, 27c arranged in the stacked body 400 to oppose to each other are viewed, the magnetic layer 29 formed on the surface of the conductor portion is arranged to surround outer peripheries of magnetic paths (indicated with a broken line) of the inductor patterns 27b, 27c. As the result that the magnetic layer 29 is arranged to surround the magnetic paths in this manner, the coupling performance between the inductor patterns 27b, 27c can be improved and also inductances of the inductor patterns 27b, 27c can be improved.

This magnetic layer 29 acts completely similarly on the inductor pattern 27 used to execute the power feeding action between the semiconductor devices and the inductor pattern 26 used to transmit and receive the signal. In other words, the magnetic layer 29 is deposited and formed on the surfaces of the conductor portions of the inductor pattern 26, 27. Therefore, the mutual coupling performance between the inductor patterns can be improved, and the effective inductance can be increased. As a result, the signal transmitting and receiving action and the power feeding action can be done firmly and effectively.

In this way, it is possible to transmit and receive the signal and feed the power between the wiring substrate 50 and all the semiconductor devices 401, 402, 403 constituting the stacked body 400 of the semiconductor devices.

In other words, according to the semiconductor device mounting structure of the present embodiment, the signal transmitting and receiving action and the power feeding action between the wiring substrate 50 and the stacked body 400 of the semiconductor devices can be done via the inductor pattern 26, 27, 52, 54. As a result, the wiring substrate 50 and the stacked body 400 are connected substantially electrically to each other.

A feature of the semiconductor device mounting structure of the present embodiment resides in such a structure that the semiconductor devices 401, 402, 403 being arranged discretely are connected electrically mutually. In this manner, the semiconductor devices 401, 402, 403 can be connected electrically in a state that these devices are still arranged discretely, not to form the structure such as the through electrode, or the like, which connect directly electrically these devices, in the semiconductor devices 401, 402, 403. As a result, such advantages can be provided that the semiconductor devices can be combined arbitrarily and stacked in assembling the stacked body 400 and also the number of stacked semiconductor devices can be set arbitrarily.

Also, in order to explain plainly the electromagnetic inducing action produced by the inductor patterns, FIGS. 6 and 7 show an example where the inductor patterns 26, 27 are not opposedly arranged in the same semiconductor device. In this case, as shown in FIG. 3D, such a structure may be of course employed that the inductor patterns 26, 27 provided to the semiconductor elements in the same semiconductor device are opposedly arranged. Since respective structures of the semiconductor devices are standardized and unified in this manner, the works applied to form the stacked body by stacking the semiconductor devices can be further simplified.

When the inductor patterns of the semiconductor elements constituting the same semiconductor device are opposedly arranged, in some cases an induced current may be produced in the inductor patterns, in which the induced current should not be produced, because the inductor patterns have the same arrangement mutually. In such case, as shown FIGS. 6 and 7, respective positions of the inductor patterns formed in the same semiconductor device may be displaced mutually. When the positions of the inductor patterns are displaced in this manner, the semiconductor devices must be combined together in forming the stacked body by stacking the semiconductor devices such that the inductor patterns used to transmit and receive the signal and feed the power between the adjacent semiconductor devices should be opposedly arranged.

In the above embodiment, an example where one inductor pattern 26 used to transmit and receive the signal and one inductor pattern 27 used to feed the power are provided respectively is illustrated. But a plurality of inductor patterns used to transmit and receive the signal may be provided to one semiconductor element. Also, only the inductor pattern used to feed the power may be provided without the provision of the inductor pattern used to transmit and receive the signal.

Also, an approach of forming the semiconductor elements 20a, 21a constituting the semiconductor device into the same planar shape is advantageous in the handling ease, and the like that. But another approach of shaping the semiconductor elements 20a, 21a in different sizes or forming them into different shapes should not be excluded. Also, when the semiconductor device is to be mounted on the wiring substrate 50, the semiconductor device can be of course mounted singly. In this case, the inductor pattern can be provided only to one semiconductor element out of the semiconductor elements constituting the semiconductor device.

What is claimed is:

1. A semiconductor device comprising:
two semiconductor elements, each having a device layer, the two semiconductor elements being jointed together to oppose the respective device layers to each other, at least one of semiconductor elements having an inductor pattern and a bump on a surface of the device layer, the bump connecting electrically the semiconductor elements and supporting and electrically isolating the inductor pattern and the opposedly arranged semiconductor element; and
an electrically insulating material filled in a space between opposing surfaces of the semiconductor elements.

2. A semiconductor device according to claim 1, wherein the inductor pattern is used for transmitting and receiving a signal or for feeding a power.

3. A semiconductor device according to claim 1, wherein at least one inductor pattern for transmitting and receiving the signal and at least one inductor pattern for feeding the power are provided to the semiconductor elements respectively.

4. A semiconductor device according to claim 1, wherein the semiconductor elements have the inductor patterns on the surfaces of the device layers, respectively, so as to oppose to each other.

5. A semiconductor device according to claim 1, wherein the bump is a solder bump.

6. A semiconductor device according to claim 1, wherein the bump is a gold bump.

7. A semiconductor device according to claim 6, wherein the semiconductor elements have the gold bumps on the surfaces of the device layers, respectively, so as to oppose to each other, and
the electrically insulating material is an anisotropic conductive resin, and the gold bumps provided in opposing positions are connected electrically mutually via the anisotropic conductive resin.

8. A method of manufacturing a semiconductor device, comprising:
a step of forming an inductor pattern on a surface of a device layer formed on a semiconductor wafer;
a step of forming a bump on the surface of the device layer formed on the semiconductor wafer;
a step of arranging two semiconductor wafers, on each of which the inductor pattern and the bump are formed, to oppose respective device layers to each other, and joining the bumps together;
a step of filling an electrically insulating material into a space between opposing surfaces of two semiconductor wafers being joined via the bumps to form a jointed body; and
a step of forming individual semiconductor devices, by dicing the joined body into individual pieces.

9. A method of manufacturing a semiconductor device, according to claim 8, wherein, in the step of forming the bump, a solder bump is formed as the bump, and
in the step of joining the bumps, the bumps are joined by a reflow soldering.

10. A method of manufacturing a semiconductor device, according to claim 8, wherein the inductor pattern is used for transmitting and receiving a signal or for feeding a power.

11. A method of manufacturing a semiconductor device, comprising:
a step of forming an inductor pattern on a surface of a device layer formed on a semiconductor wafer;
a step of forming a gold bump on the surface of the device layer formed on the semiconductor wafer;
a step of interposing an anisotropic conductive resin between opposing surfaces of two semiconductor wafers on each of which the inductor pattern and the gold bump are formed, and connecting electrically the opposing gold bumps and filling the anisotropic conductive resin into a space between the opposing surfaces of the two semiconductor wafers by pressing the two semiconductor wafers from both surface sides to form a jointed body; and
a step of forming individual semiconductor devices, by dicing the joined body into individual pieces.

12. A method of manufacturing a semiconductor device, according to claim 11, wherein the inductor pattern is used for transmitting and receiving a signal or for feeding a power.

13. A semiconductor device mounting structure, comprising:
a wiring substrate; and
a semiconductor device according to claim 1, mounted on the wiring substrate,
wherein the wiring substrate has another inductor pattern formed in an position opposed in planarly to the inductor pattern provided to the semiconductor device so that an electromagnetic inducing action is produced between the another inductor pattern and the inductor pattern provided to the semiconductor device.

14. A semiconductor device mounting structure, according to claim 13, wherein the another inductor pattern is used for transmitting and receiving a signal or for feeding a power.

15. A semiconductor device mounting structure, according to claim 13, wherein a plurality of the semiconductor device are stacked to form a stacked body, and
the semiconductor devices constituting the stacked body are provided in positions, in which the inductor patterns provided on neighboring semiconductor elements oppose planarly to each other, between the semiconductor devices located in neighboring positions in a stacking direction.

16. A semiconductor device mounting structure, according to claim 15, wherein the inductor patterns provided to the semiconductor devices constituting the stacked body are provided in common positions having same planar positions in all semiconductor devices.
